(19) United States
(12) Patent Application Publication
(10) Pub. No.: US 2009/0161888 A1
(43) Pub. Date: Jun. 25, 2009

(54) AUTO GAIN CONTROL AMPLIFIER, AUTO GAIN CONTROL SYSTEM AND AUTO GAIN CONTROL METHOD

(75) Inventor: Koji OKADA, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU MICROELECTRONICS LIMITED, Tokyo (JP)

(21) Appl. No.: 12/276,748

(22) Filed: Nov. 24, 2008

(30) Foreign Application Priority Data
Dec. 21, 2007 (JP) 2007-330458

(51) Int. Cl. H03G 3/00

(52) U.S. Cl. 381/107; 330/278

(57) ABSTRACT

An auto gain control amplifier that amplifies an input signal including a variable gain amplification unit that amplifies an input signal and an auto gain control unit that monitors amplitude of an output signal of the variable gain amplification unit, obtains an gain of the variable gain amplification unit that causes the amplitude of the output signal to fall within a desired range according to the amplitude of the output signal, and supplies the gain obtained to the variable gain amplification unit. The auto gain control unit sets the gain in the variable gain amplification unit when the amplitude of the output signal is equal to or below a predetermined reference value.

### CROSS-REFERENCE TO RELATED APPLICATIONS

This application claims the benefit of priority from Japanese Patent Application No. 2007-330458 filed on Dec. 21, 2007, the entire contents of which are incorporated herein by reference.

### BACKGROUND OF THE INVENTION

1. Field of the Invention

This application relates to an auto gain control amplifier.

2. Description of Related Art

Auto gain control amplifiers monitor an output level of an amplifier and automatically control the gain of the amplifier so that the output level falls within an appropriate range. A voice recording apparatus such as a digital voice recorder that digitizes and records a voice signal has the auto gain control amplifier and a memory that digitizes and records the output of the amplifier. The auto gain control amplifier has a variable gain amplifier that amplifies an electric signal output from a microphone and an auto gain control unit that controls the gain of the variable gain amplifier so that the output level from the variable gain amplifier falls within an appropriate range.

Japanese Laid-open Patent Publication No. H11-284460 discloses an amplifier-related technique.

### SUMMARY

Aspects of an embodiment include an auto gain control amplifier that amplifies an input signal. The auto gain control amplifier comprises a variable gain amplification unit that amplifies an input signal and an auto gain control unit that monitors amplitude of an output signal of the variable gain amplification unit, obtains a gain of the variable gain amplification unit that causes the amplitude of the output signal to fall within a desired range according to the amplitude of the output signal, and supplies the gain obtained to the variable gain amplification unit. The auto gain control unit sets the gain in the variable gain amplification unit when the amplitude of the output signal is equal to or below a predetermined reference value.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 shows aspects of an auto gain control amplifier;

FIG. 2 shows aspects of an output signal of a variable gain amplification unit;

FIG. 3 shows aspects of a first embodiment;

FIG. 4 shows aspects of an output signal of the variable gain amplification unit;

FIG. 5 shows aspects of an example of an auto gain control unit;

FIG. 6 shows a flowchart of an auto gain control program;

FIG. 7 shows aspects of an example of a programmable gain amplifier;

FIG. 8 shows aspects of another example of the programmable gain amplifier;

FIG. 9 shows aspects of yet another example of the programmable gain amplifier;

FIG. 10 shows aspects of yet another example of the programmable gain amplifier;

FIG. 11 shows aspects of a second embodiment;

FIG. 12 shows aspects of an output signal of a variable gain amplification unit;

FIG. 13 shows a flowchart of the auto gain control program;

FIG. 14 shows aspects of an example of a second embodiment;

FIG. 15 shows aspects of an output signal of a variable gain amplification unit;

FIG. 16 shows aspects of another example of the second embodiment; and

FIG. 17 shows aspects of an output signal of the auto gain control amplifier.

### DESCRIPTION OF PREFERRED EMBODIMENTS

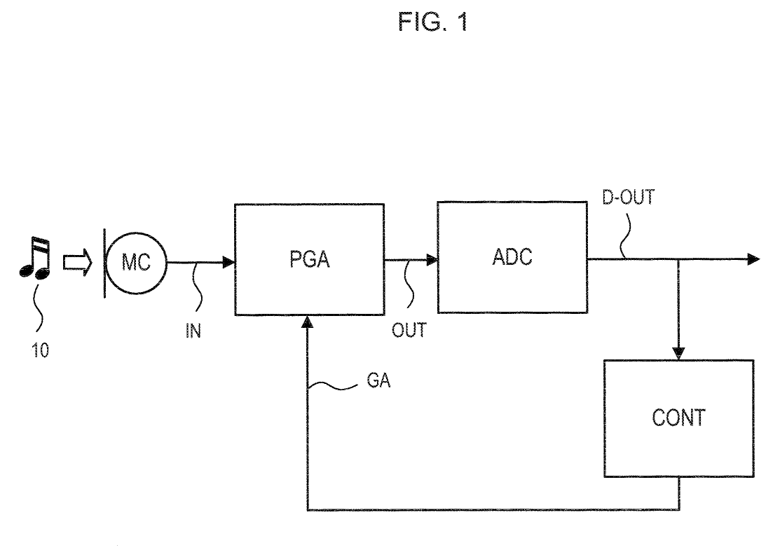

FIG. 1 shows an auto gain control amplifier. The auto gain control amplifier has a variable gain amplification unit PGA, an analog digital converter ADC and an auto gain control unit CONT. A microphone MC converts a voice 10 to a voice signal IN, which is an electric signal. The variable gain amplification unit (programmable gain amplifier) PGA amplifies the voice signal IN and outputs an output voice signal OUT. The analog digital converter ADC converts the output voice signal OUT to a digital voice signal D-OUT. The auto gain control unit CONT monitors the amplitude of the digital voice signal D-OUT, calculates an appropriate gain GA so that the amplitude falls within a desired amplitude range, and sets the appropriate gain GA in the variable gain amplification unit PGA.

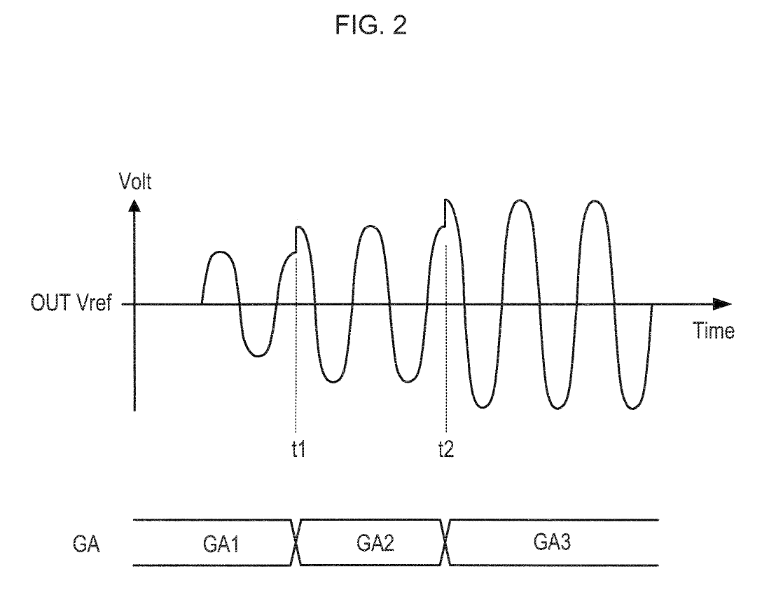

FIG. 2 shows a waveform of the output voice signal OUT of the variable gain amplification unit PGA and the appropriate gain GA generated by the auto gain control unit CONT. The voice signal OUT includes a DC-component signal waveform and oscillates toward the plus side and minus side centered on a central voltage Vref. When the amplifier PGA is set to a gain GA1, the auto gain control unit CONT generates a new appropriate gain GA2 at a time t1 and sets the appropriate gain GA2(>GA1) in the amplifier PGA. At the time t1, the amplitude of the output voice signal OUT of the amplifier PGA drastically increases. When the amplifier PGA is set to the gain GA2, the auto gain control unit CONT generates a new appropriate gain GA3 at a time t2 and sets an appropriate gain GA3(>GA2) in the amplifier PGA. At the time t2, the amplitude of the output voice signal OUT of the amplifier PGA drastically increases. At the times t1 and t2, high-frequency noise occurs at the output voice signal OUT and a pop sound occurs.

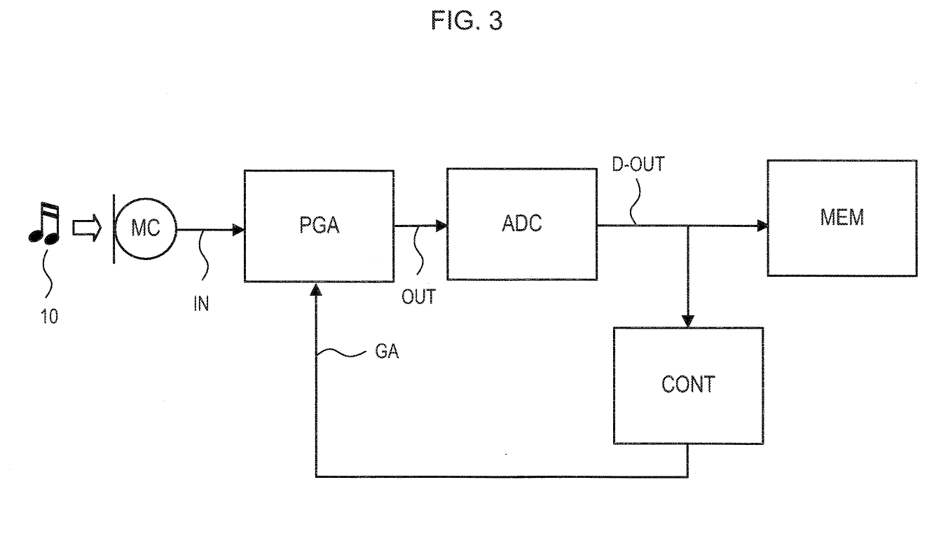

FIG. 3 shows aspects of a first embodiment. A voice recording apparatus in FIG. 3 has an auto gain control amplifier and a memory unit MEM. The auto gain control amplifier has a variable gain amplification unit PGA, an analog digital converter ADC and an auto gain control unit CONT. A microphone MC converts a voice 10 to a voice signal IN which is an electric signal. The variable gain amplification unit (programmable gain amplifier) PGA amplifies the voice signal IN and outputs an output voice signal OUT. The analog digital converter ADC converts the output voice signal OUT to a digital voice signal D-OUT. The auto gain control unit CONT monitors the amplitude of the digital voice signal D-OUT, calculates an appropriate gain GA so that the amplitude falls within a desired amplitude range, and sets the appropriate gain GA in the variable gain amplification unit PGA.

The analog digital converter ADC converts the analog output voice signal OUT to a digital voice signal D-OUT in synchronization with a sampling clock (not shown). The digital voice signal D-OUT is recorded in the memory unit MEM.

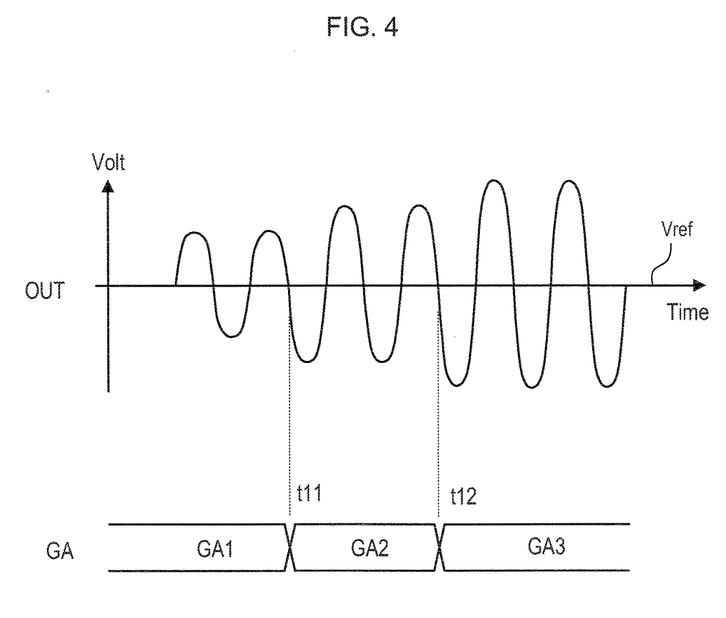

FIG. 4 shows aspects of a waveform of the output voice signal OUT of the variable gain amplification unit PGA. The auto gain control unit CONT generates new appropriate gains GA2 and GA3 at timing t11 and t12 at which the amplitude of the output voice signal OUT becomes 0, and sets the appropriate gains GA2 and GA3 in the variable gain amplification unit PGA.

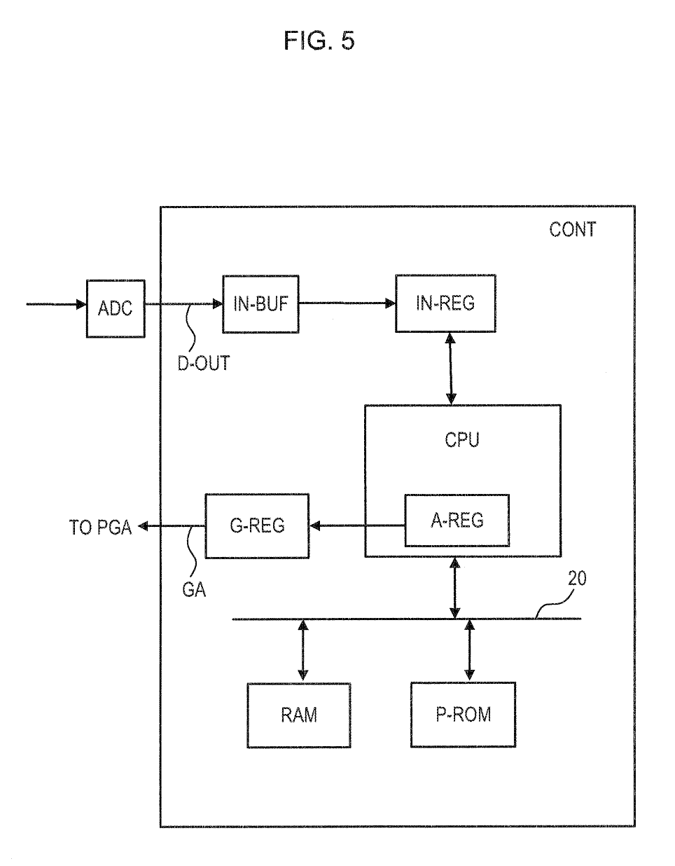

FIG. 5 shows aspects of an example of the auto gain control unit CONT. The auto gain control unit CONT is, for example, a general-purpose microcomputer. The auto gain control unit CONT includes a central processing unit CPU, a CPU bus 20, a program memory P-ROM and an internal memory RAM. The auto gain control unit CONT includes an input buffer IN-BUF that receives the digital voice signal D-OUT output from the analog digital converter ADC, an input register IN-REG that temporarily stores the digital voice signal D-OUT, and a gain register G-REG that stores an appropriate gain signal GA generated by the central processing unit CPU. The central processing unit CPU includes, for example, a general register A-REG and a calculation circuit (not shown) or the like. The digital voice signal D-OUT is, for example, a 16-bit digital signal indicating the magnitude of the amplitude of the voice signal OUT.

The program memory P-ROM stores an auto gain control program. The auto gain control program generates an appropriate gain, detects timing at which the voice signal D-OUT falls at or below a reference value or falls to 0, and outputs an appropriate gain GA generated at the detected timing. The central processing unit CPU executes an auto gain control program.

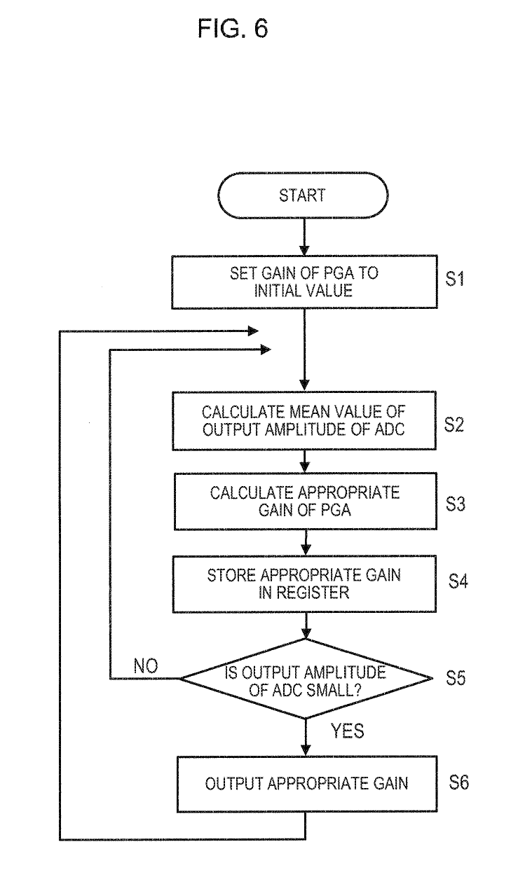

FIG. 6 shows a flowchart of the auto gain control program. The auto gain control unit CONT executes the auto gain control program in response to power-up or the like. First, the gain of the variable gain amplifier PGA is set to an initial value (S1). The central processing unit CPU outputs the initial value to the gain register G-REG and the initial value is thereby set in the variable gain amplifier PGA.

The digital voice signal D-OUT, which is output from the analog digital converter ADC in synchronization with a sampling clock (not shown), is stored in the input register IN-REG in the auto gain control unit CONT. The central processing unit CPU receives the stored digital voice signals D-OUT (amplitude values of the voice signal) successively and calculates a mean value within a predetermined period (S2). The central processing unit CPU calculates such an appropriate gain GA that the mean value of the amplitude of the output voice signal of the variable gain amplifier PGA falls within a desired range (S3). The appropriate gain GA is stored in the general register A-REG (S4). The “desired range” means that the amplitude of the output voice signal OUT is within a dynamic range of the variable gain amplifier PGA and the magnitude of the amplitude of the output voice signal OUT falls within an audible range. A small voice is amplified appropriately, a large voice is attenuated appropriately, and the output voice signal OUT becomes the desired range.

The central processing unit CPU monitors the digital voice signal D-OUT stored in the input register IN-REG and detects a time at which the amplitude of the digital voice signal falls at or below a reference value or falls to 0 (S5). The central processing unit CPU outputs the appropriate gain GA in the general register A-REG to the gain register G-REG when the digital voice signal D-OUT falls at or below the reference value or falls to 0 (S6).

The central processing unit CPU repeats operations S2, S3 and S4 shown in FIG. 6 and updates a new appropriate gain GA in the general register A-REG. The operations may be repeated all the time. When the digital voice signal D-OUT falls at or below the reference value or falls to 0, the central processing unit CPU outputs the appropriate gain GA in the general register A-REG to the gain register G-REG. The appropriate gain GA is set in the variable gain amplifier PGA. As shown in FIG. 4, at the times t11 and t12 at which the gain GA is changed, any drastic increase or decrease of the amplitude of the output voice signal OUT is prevented and no pop sound occurs.

A voice signal has a frequency on the order of approximately 20 KHz and microprocessors currently being widely used have a frequency of several MHz to 2 GHz. The sampling rate of a compact disk (CD) in which voice data is recorded is on the order of 44 KHz. Therefore, the auto gain control unit CONT which is a high-speed microprocessor samples the voice signal IN, calculates a mean value of the amplitude of the sampled voice signal, and may obtain an appropriate gain.

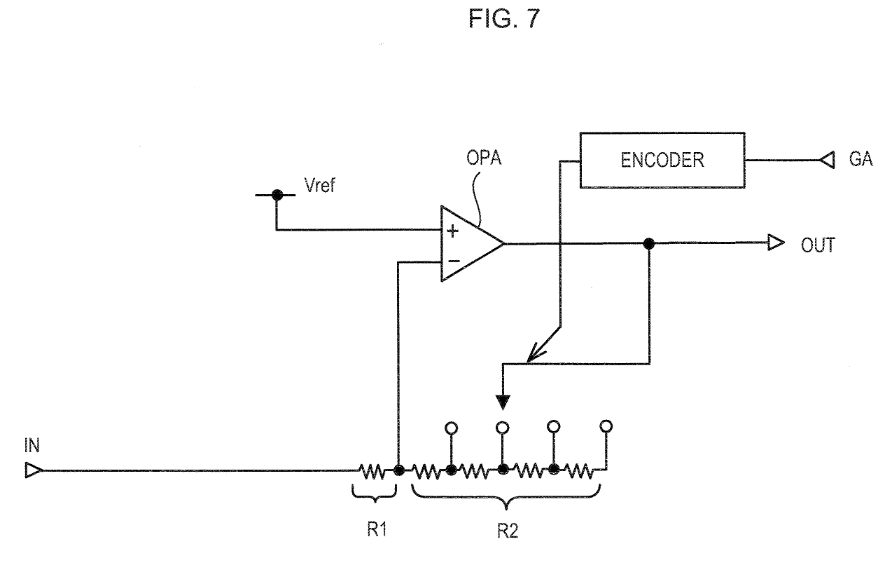

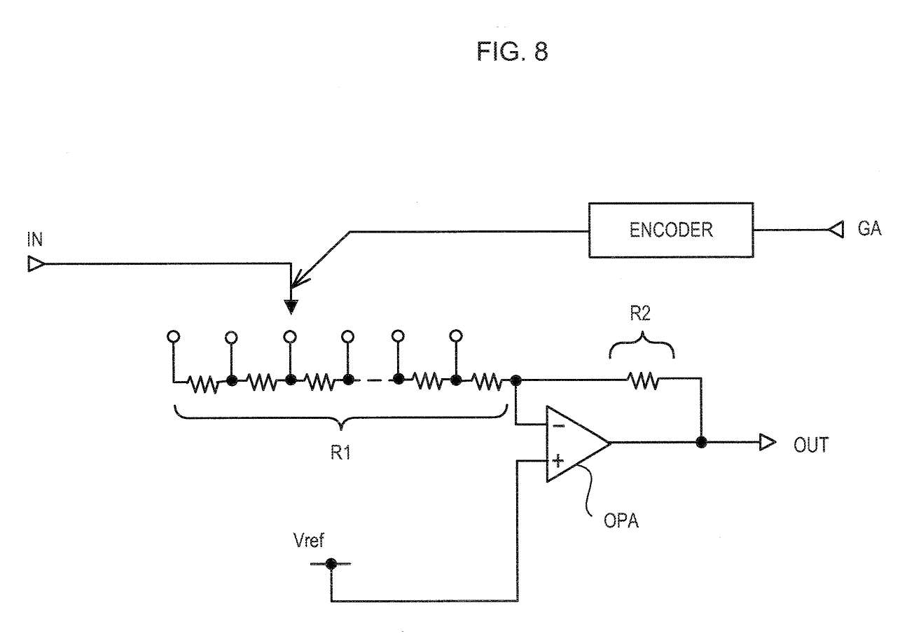

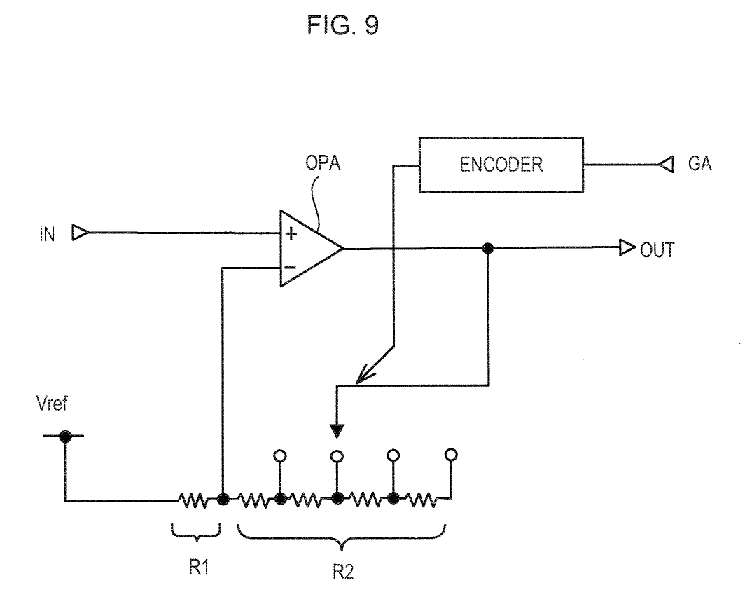

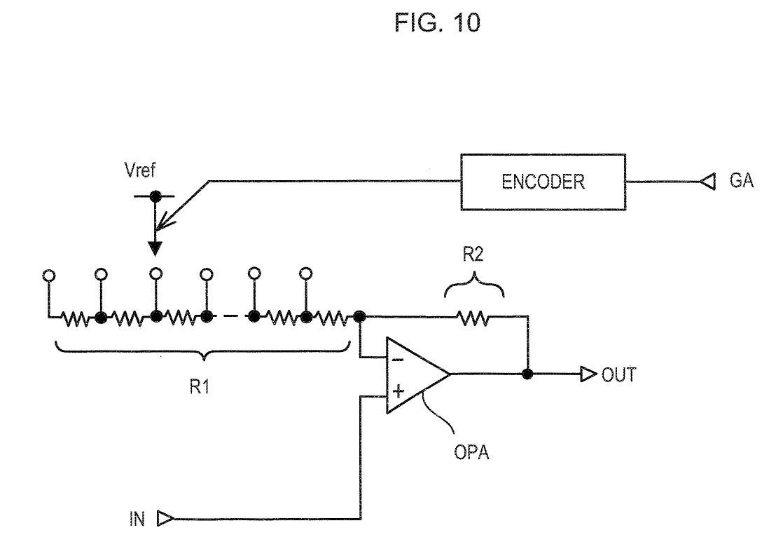

FIG. 7 to FIG. 10 show aspects of examples of the programmable gain amplifier. The programmable gain amplifiers shown in FIG. 7 to FIG. 10 include an operational amplifier OPA, amplify an input signal IN, and output an output signal OUT. An encoder ENCODER encodes a gain GA (control signal). A connection point between a variable resistor R2 and an output terminal OUT is selected based on the encoded value. The programmable gain amplifiers shown in FIG. 7 and FIG. 8 are inverted amplification units. The programmable gain amplifiers shown in FIG. 9 and FIG. 10 are non-inverted amplification units.

In the programmable gain amplifier shown in FIG. 7, a central voltage Vref corresponding to a central voltage of a voice signal IN is applied to a positive input terminal of the operational amplifier OPA and the voice signal IN is applied to a negative input terminal of the operational amplifier OPA through a resistor R1. An output terminal OUT is coupled to any one of connection points of a variable resistor R2 in accordance with the output of the encoder. The gain of the programmable gain amplifier shown in FIG. 7 is −R2/R1. The gain is changed from 0 to a maximum value by changing the variable resistor R2.

In the programmable gain amplifier in FIG. 8, a central voltage Vref is applied to a positive input terminal of the operational amplifier OPA and a voice signal IN is applied to a negative input terminal of an operational amplifier OPA through a variable resistor R1. An input terminal IN is coupled to any one of a plurality of connection points of the variable resistor R1 in accordance with the output of the encoder. The gain of the programmable gain amplifier shown in FIG. 8 is −R2/R1. The gain is changed by changing the variable resistor R1.

In the programmable gain amplifier in FIG. 9, a voice signal IN is applied to a positive input terminal of an operational amplifier OPA and a central voltage Vref is applied to a negative input terminal of the operational amplifier OPA through a variable resistor R1. An output terminal OUT is coupled to any one of a plurality of connection points of a variable resistor R2 in accordance with the output of the encoder. The gain of the programmable gain amplifier shown in FIG. 9 is 1+(R2/R1). The gain is changed from 1 to a maximum value by changing the variable resistor R2.

In the programmable gain amplifier in FIG. 10, a voice signal IN is applied to a positive input terminal of an operational amplifier OPA and a central voltage Vref is applied to a negative input terminal of the operational amplifier OPA through a variable resistor R1. A central voltage terminal is coupled to any one of a plurality of connection points of the variable resistor R1 in accordance with the output of the encoder. The gain of the programmable gain amplifier shown in FIG. 10 is 1+(R2/R1). The gain is changed from 1 to a maximum value by changing the variable resistor R1.

In the first embodiment, the auto gain control unit CONT detects timing at which the amplitude of the output signal OUT falls at or below a reference value or falls to 0. The central processing unit CPU of the auto gain control unit CONT may also predictively calculate a time at which the amplitude of the output voice signal will fall at or below the reference value or will fall to 0 based on the variation of the amplitude of the output voice signal D-OUT and output the appropriate gain GA to the gain register G-REG at the predicted timing. The central processing unit CPU calculates the gradient of the amplitude of the output voice signal D-OUT from a variation thereof and predicts, based on the calculated gradient, the timing at which the amplitude of the output voice signal will fall at or below the reference value or will fall to 0. Carrying out predictive calculations at a certain intervals eliminates the necessity for constant monitoring of the amplitude of the output signal D-OUT.

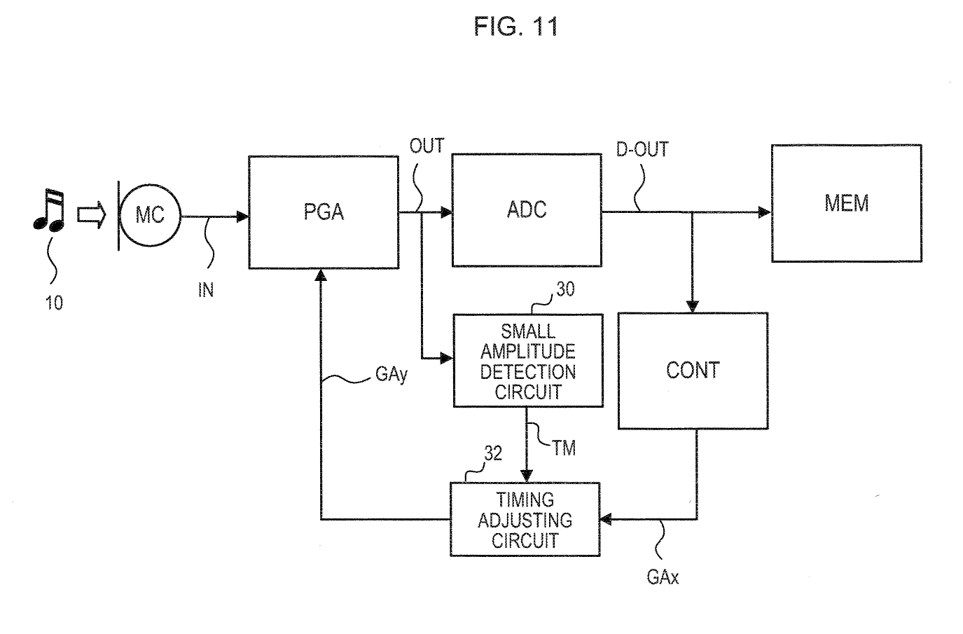

FIG. 11 shows a second embodiment. Unlike the voice recording apparatus of the first embodiment shown in FIG. 3, the voice recording apparatus according to the second embodiment includes a small amplitude detection circuit 30 and a timing adjusting circuit 32. The small amplitude detection circuit 30 detects that an analog output signal OUT of an amplifier PGA comes to have small amplitude equal to or below a reference value and outputs a timing signal TM. In response to the timing signal TM, the timing adjusting circuit 32 receives an appropriate gain GAx generated by an auto gain control unit CONT and outputs an appropriate gain GAy to the programmable gain amplifier PGA. The programmable gain amplifier PGA and an analog digital converter ADC are the same as or similar to those shown in FIG. 3. Like the first embodiment, the auto gain control unit CONT monitors a digital voice signal D-OUT and generates an appropriate gain GAx.

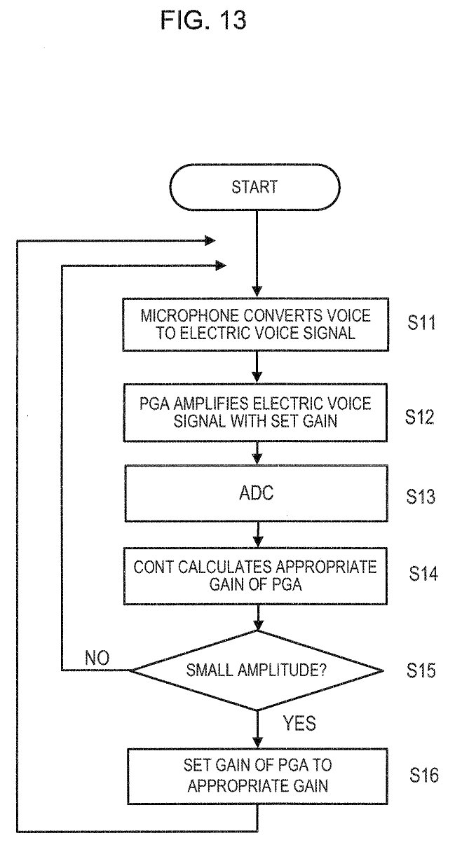

FIG. 13 shows a flowchart of the auto gain control amplifier. The voice microphone MC converts the voice 10 to an electric signal and generates the voice signal IN (S11). The programmable gain amplifier PGA amplifies the voice signal IN with a set gain (S12). The analog digital converter ADC converts the output voice signal OUT of the programmable gain amplifier PGA to a digital voice signal D-OUT (S13). The auto gain control unit CONT, which is a microprocessor, calculates the appropriate gain GAx of the programmable gain amplifier PGA based on the amplitude of the digital voice signal D-OUT and outputs the appropriate gain GAx (S14). The small amplitude detection circuit 30 detects the timing at which the amplitude of the output voice signal OUT of the programmable gain amplifier PGA becomes 0 (or equal to or below a reference value) and outputs a timing signal TM (YES in S15). The timing adjusting circuit 32 receives the appropriate gain GAx in response to the timing signal TM and sets the appropriate gain GAy in the programmable gain amplifier PGA (S16).

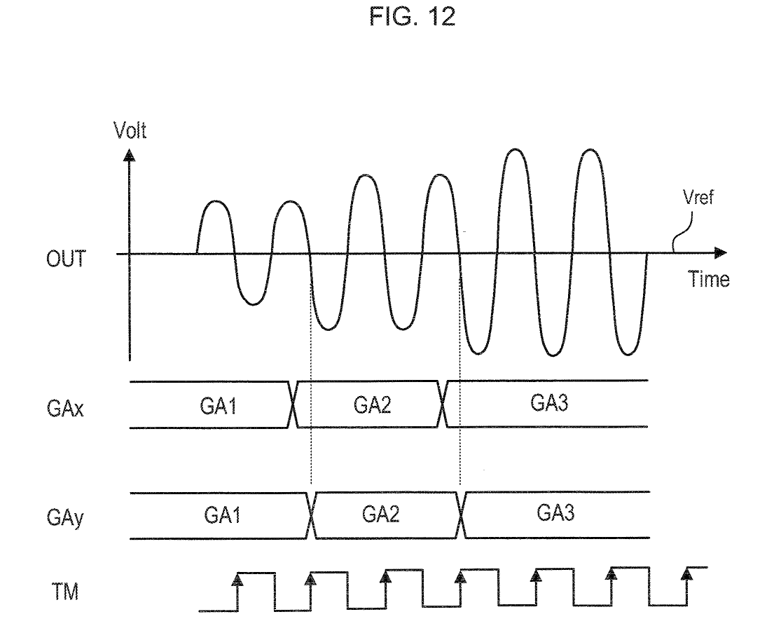

FIG. 12 shows a waveform of the output voice signal OUT of the variable gain amplification unit (programmable gain amplifier) PGA. In FIG. 12, the output voice signal OUT, appropriate gain GAx and GAy and timing signal TM are shown. The timing signal TM is a signal that rises when the output voice signal OUT turns from minus to plus with respect to the central voltage Vref. The timing adjusting circuit 32 receives the appropriate gain GAx at a rising-edge of the timing signal TM and outputs the appropriate gain GAy to the programmable gain amplifier PGA.

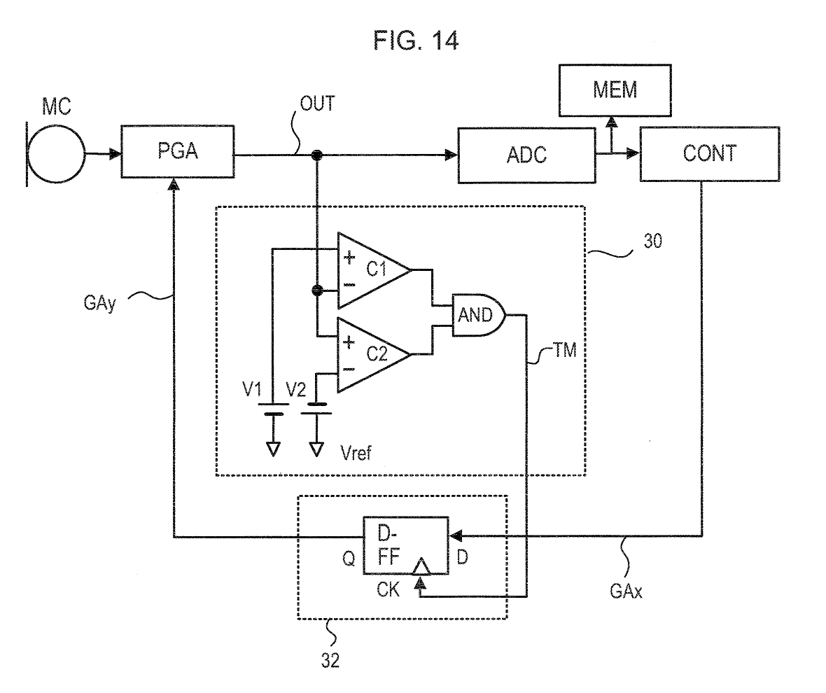

FIG. 14 shows aspects of an example of the second embodiment. The small amplitude detection circuit 30 includes comparators C1 and C2 and an AND gate that outputs a logical product of the outputs of the comparators C1 and C2 as a timing signal TM. Vref+V1 is input to a positive input terminal of the comparator C1 as a reference voltage and an output voice signal OUT is input to a negative input terminal of the comparator C1. The output voice signal OUT is input to a positive input terminal of the comparator C2 and Vref−V2 is input to a negative input terminal of the comparator C2 as a reference voltage.

The comparator C1 outputs a high level signal when the output voice signal OUT is lower than the reference voltage Vref+V1 and outputs a low level signal when the output voice signal OUT is higher than the reference voltage Vref+V1. The comparator C2 outputs a low level signal when the output voice signal OUT is lower than the reference voltage Vref−V2 and outputs a high level signal when the output voice signal OUT is higher than the reference voltage Vref−V2. The timing signal TM output from the AND gate becomes a high level when the amplitude of the output voice signal OUT falls at or below the reference value (−V2≦OUT≦V1). The timing signal TM becomes a high level when the output voice signal OUT turns from plus to minus with respect to the central voltage Vref.

The timing adjusting circuit 32 includes a D flip flop D-FF. The D flip flop D-FF receives the appropriate gain GAx in response to a rising edge of the timing signal TM input to the clock terminal CK and outputs the appropriate gain GAy.

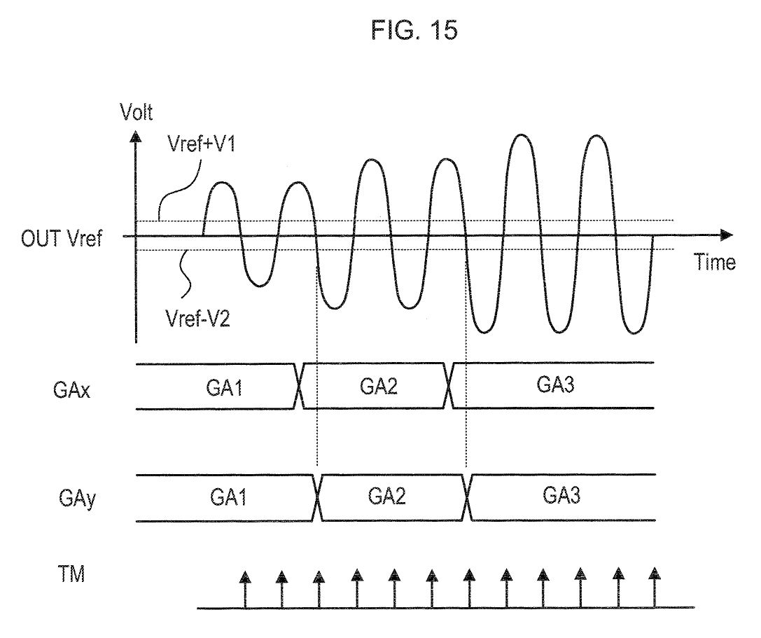

FIG. 15 shows a waveform of the output voice signal OUT of the variable gain amplification unit (programmable gain amplifier) PGA. In FIG. 15, the output voice signal OUT, appropriate gains GAx and GAy and timing signal TM are shown.

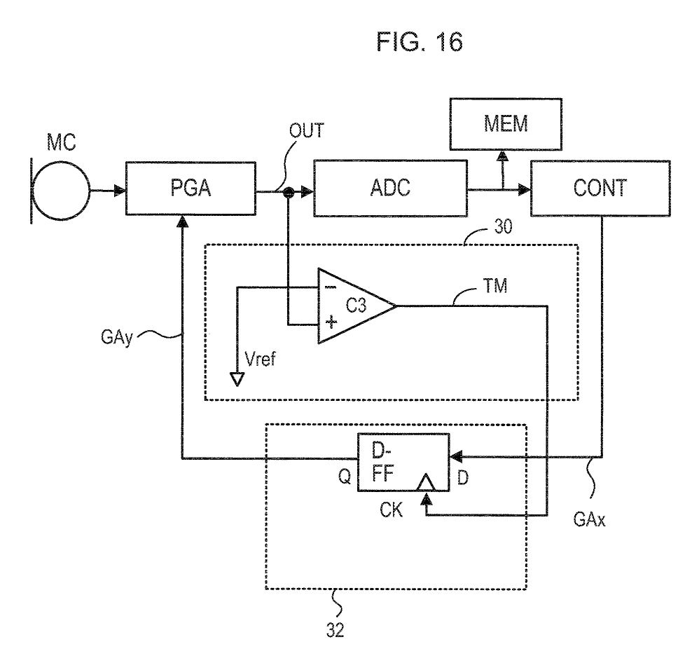

FIG. 16 shows aspects of another example of the second embodiment. The small amplitude detection circuit 30 includes a comparator C3, to a positive input terminal of which an output voice signal OUT is input and to a negative input terminal of which a central voltage Vref is input. The comparator C3 outputs a high level signal when the output voice signal OUT is higher than the central voltage and outputs a low level signal when the output voice signal OUT is lower than the central voltage. The timing signal TM becomes a high level when the output voice signal OUT turns from minus to plus with respect to the central voltage Vref and becomes a low level when the output voice signal OUT turns from plus to minus. The timing signal TM becomes a high level when the amplitude of the output voice signal OUT becomes 0 in the process in which the amplitude of the output voice signal OUT turns from minus to plus. The timing adjusting circuit 32 is the same as or similar to the circuit shown in FIG. 14.

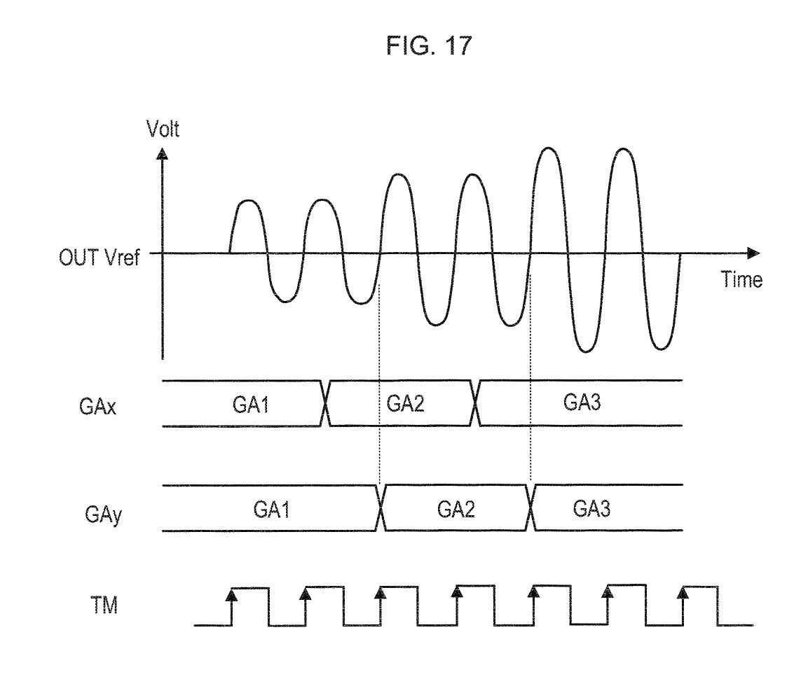

FIG. 17 shows a waveform of the output voice signal OUT of the variable gain amplification unit (programmable gain amplifier) PGA. In FIG. 17, output voice signal OUT, appropriate gains GAx and GAy and timing signal TM are shown.

Aspects of the second embodiment include the small amplitude detection circuit 30 and timing adjusting circuit 32, which are hardware. In the second embodiment, as in the first embodiment, the gain of the amplifier PGA is changed when the amplitude of the output voice signal OUT of the programmable gain amplifier PGA falls at or below a reference value or falls to 0. The second embodiment prevents a pop sound upon the change of the gain.

Example embodiments of the present invention have now been described in accordance with the above advantages. It will be appreciated that these examples are merely illustrative of the invention. Many variations and modifications will be apparent to those skilled in the art.

1. An auto gain control amplifier that amplifies an input signal, comprising:
a variable gain amplification unit that amplifies an input signal; and
an auto gain control unit that monitors amplitude of an output signal of the variable gain amplification unit, obtains a gain of the variable gain amplification unit that causes the amplitude of the output signal to fall within a desired range as a function of the amplitude of the output signal, and supplies the gain obtained to the variable gain amplification unit,
wherein the auto gain control unit sets the gain in the variable gain amplification unit when the amplitude of the output signal is equal to or below a predetermined reference value.

2. The auto gain control amplifier according to claim 1, wherein the auto gain control unit monitors whether or not the amplitude of the output signal is equal to or below the reference value and sets the gain when the amplitude of the output signal is detected to fall at or below the reference value.

3. The auto gain control amplifier according to claim 1, wherein the auto gain control unit predicts a time at which the amplitude of the output signal falls at or below the reference value based on the variation of the amplitude of the output signal and sets the gain at the predicted time.

4. The auto gain control amplifier according to claim 1, further comprising:
an analog digital converter that converts the output signal to a digital signal and supplies the digital signal to the auto gain control unit.

5. The auto gain control amplifier according to claim 1, wherein the auto gain control unit includes a microprocessor.

6. The auto gain control amplifier according to claim 1, wherein the auto gain control unit comprises:
a detection unit that compares an output signal of the variable gain amplification unit with the reference value and outputs a timing signal when the amplitude of the output signal falls at or below the reference value; and
a timing adjusting circuit that outputs a gain to the variable gain amplification unit in response to the timing signal.

7. The auto gain control amplifier according to claim 1, wherein the reference value is a value that corresponds to the amplitude of the output signal at 0.

8. The auto gain control amplifier according to claim 1, wherein the input signal is an audio signal.

9. The auto gain control amplifier according to claim 1, further comprising a memory unit that stores an output signal of the variable gain amplification unit.

10. The auto gain control amplifier according to claim 1, wherein the variable gain amplification unit comprises:
an input terminal that receives the input signal;
an operational amplifier that amplifies the input signal; and
a switch that couples the input terminal and an output of the operational amplifier based on the gain.

11. The auto gain control amplifier according to claim 10, wherein the variable gain amplification unit is one of an inverted amplification unit and a non-inverted amplification unit.

12. An auto gain control system comprising:
an input unit that receives an input signal;
a variable gain amplification unit that amplifies the input signal; and
an auto gain control unit that monitors amplitude of an output signal of the variable gain amplification unit, obtains a gain of the variable gain amplification unit that causes the amplitude of the output signal to fall within a desired range according to the amplitude of the output signal, and supplies the gain obtained to the variable gain amplification unit,
wherein the auto gain control unit sets the gain in the variable gain amplification unit when the amplitude of the output signal is equal to or below a predetermined reference value.

13. The auto gain control system according to claim 12, further comprising:
an analog digital conversion unit that converts the output signal to a digital signal and supplies the digital signal to the auto gain control unit.

14. The auto gain control system according to claim 12, further comprising:
a memory unit that stores the output signal of the variable gain amplification unit.

15. The auto gain control system according to claim 12, wherein the input signal is an audio signal, and the input unit includes a microphone.

16. The auto gain control system according to claim 12, wherein the auto gain control unit includes a microprocessor.

17. An auto gain control method comprising:
amplifying an input signal;
converting the amplified input signal to a digital signal; and
calculating a gain that causes amplitude of the digital signal to fall within a desired range based on the digital signal; and
outputting the gain when the amplitude of the amplified signal is equal to or below a predetermined reference value.

18. The auto gain control method according to claim 17, further comprising:
calculating a mean value of the digital signal within a predetermined period; and
obtaining the gain based on the mean value.

19. The auto gain control method according to claim 17, further comprising:
storing the digital signal in a memory.

20. The auto gain control method according to claim 17, further comprising:
setting an initial value of the gain for amplifying the input signal in response to a power-on.
